(19) United States
(12) Patent Application Publication
(10) Pub. No.: US 2006/0193159 A1
(43) Pub. Date: Aug. 31, 2006

(54) Fast pattern matching using large compressed databases

(75) Inventors: Teewoon Tan, Roseville (AU); Stephen Gould, Killara (AU); Darren Williams, Newtown (AU); Ernest Peltzer, Eastwood (AU); Robert Matthew Barrie, Double Bay (AU)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sensory Networks, Inc., Palo Alto, CA (US)

(21) Appl. No.: 11/326,131

(22) Filed: Jan. 4, 2006

Related U.S. Application Data
(60) Provisional application No. 60/654,224, filed on Feb. 17, 2005.

(51) Int. Cl. G11C 15/00

(52) U.S. Cl. 365/49

(57) ABSTRACT

A pattern matching system includes, in part, a multitude of databases each configured to store and supply compressed data for matching to the received data. The system divides each data stream into a multitude of segments and optionally computes a data pattern from the data stream prior to the division into a multitude of segments. Segments of the data pattern are used to define an address for one or more memory tables. The memory tables are read such that the outputs of one or more memory tables are used to define the address of another memory table. If during any matching cycle, the data retrieved from any of the successively accessed memory tables include an identifier related to any or all previously accessed memory tables, a matched state is detected. A matched state contains information related to the memory location at which the match occurs as well as information related to the matched pattern, such as the match location in the input data stream.

### CROSS-REFERENCES TO RELATED APPLICATIONS

The present application claims benefit under 35 USC 119(e) of U.S. provisional application No. 60/654,224, attorney docket number 021741-001900US, filed on Feb. 17, 2005, entitled “APPARATUS AND METHOD FOR FAST PATTERN MATCHING WITH LARGE DATABASES” the content of which is incorporated herein by reference in its entirety.

The present application is related to copending application Ser. No. ______, entitled “COMPRESSION ALGORITHM FOR GENERATING COMPRESSED DATABASES”, filed contemporaneously herewith, attorney docket no. 021741-001920US, assigned to the same assignee, and incorporated herein by reference in its entirety.

### BACKGROUND OF THE INVENTION

The present invention relates to the inspection and classification of high speed network traffic, and more particularly to the acceleration of classification of network content using pattern matching where the database of patterns used is relatively large in comparison to the available storage space.

Efficient transmission, dissemination and processing of data are essential in the current age of information. The Internet is an example of a technological development that relies heavily on the ability to process information efficiently. With the Internet gaining wider acceptance and usage, coupled with further improvements in technology such as higher bandwidth connections, the amount of data and information that needs to be processed is increasing substantially. Of the many uses of the Internet, such as world-wide-web surfing and electronic messaging, which includes e-mail and instant messaging, some are detrimental to its effectiveness as a medium of exchanging and distributing information. Malicious attackers and Internet-fraudsters have found ways of exploiting security holes in systems connected to the Internet to spread viruses and worms, gain access to restricted and private information, gain unauthorized control of systems, and in general disrupt the legitimate use of the Internet. The medium has also been exploited for mass marketing purposes through the transmission of unsolicited bulk e-mails, which is also known as spam. Apart from creating inconvenience for the user on the receiving end of a spam message, spam also consumes network bandwidth at a cost to network infrastructure owners. Furthermore, spam poses a threat to the security of a network because viruses are sometimes attached to the e-mail.

Network security solutions have become an important part of the Internet. Due to the growing amount of Internet traffic and the increasing sophistication of attacks, many network security applications are faced with the need to increase both complexity and processing speed. However, these two factors are inherently conflicting since increased complexity usually involves additional processing.

Pattern matching is an important technique in many information processing systems and has gained wide acceptance in most network security applications, such as anti-virus, anti-spam and intrusion detection systems. Increasing both complexity and processing speed requires improvements to the hardware and algorithms used for efficient pattern matching.

An important component of a pattern matching system is the database of patterns to which an input data stream is matched against. As network security applications evolve to handle more varied attacks, the sizes of pattern databases used increase. Pattern database sizes have increased to such a point that it is significantly taxing system memory resources, and this is especially true for specialized hardware solutions which scan data at high speed.

### BRIEF SUMMARY OF THE INVENTION

In accordance with one embodiment of the present invention, incoming network traffic is compressed using a hash function and the compressed result is used by a space-and-time efficient retrieval method that compares it with entries in a multitude of databases that store compressed data. In accordance with another embodiment of the present invention, incoming network traffic is used for comparison in the databases without being compressed using a hash function. The present invention, accordingly, accelerates the performance of content security applications and networked devices such as gateway anti-virus and email filtering appliances.

In some embodiments, the matching of the compressed data is performed by a pattern matching system and a data processing system which may be a network security system configured to perform one or more of anti-virus, anti-spam and intrusion detection algorithms. The pattern matching system is configured to support large pattern databases. In one embodiment, the pattern matching system includes, in part, a hash value calculator, a compressed database pattern retriever, and first and second memory tables.

Incoming data byte streams are received by the hash value calculator which is configured to compute the hash value for a substring of length N bytes of the input data byte stream (alternatively referred to hereinbelow as data stream). Compressed database pattern retriever compares the computed hash value to the patterns stored in first and second memory tables. If the compare results in a match, a matched state is returned to the data processing system. A matched state holds information related to the memory location at which the match occurs as well as other information related to the matched pattern, such as the match location in the input data stream. If the computed hash value is not matched to the compressed patterns stored in first and second memory tables either a no-match state is returned to the data processing system or alternatively nothing is returned to the data processing system.

A matched state may correspond to multiple uncompressed patterns. If so, the data processing system disambiguates the match by identifying a final match from among the many matches found. In such embodiments, the data processing system may be configured to maintain an internal database used to map the matched state to a multitude of original uncompressed patterns. These patterns are then compared by data processing system to the pattern in the input data stream at the location specified by the matched state so as to identify the final match.

In one embodiment, if the data read from the second memory table includes the corresponding address of the first memory table used to compute the address of the data read from the second memory table, the match validator generates a matched state signal. In such embodiments, if the data read from the second memory table does not include the corresponding address of the first memory table used to compute the address of the data read from the second memory table, the match validator generates a no-match signal. In another embodiment, if the data read from the second memory table matches an identifier stored in the corresponding address of the first memory table 150 used to compute the address of the data read from the second memory table, match validator generates a matched state signal. In such embodiments, if the data read from the second memory table does not match the identifier stored in the corresponding address of the first memory table used to compute the address of the data read from the second memory table, match validator generates a no-match signal. Match validator outputs a matched state that is used by a post processor to identify the pattern that matched.

### BRIEF DESCRIPTION OF THE DRAWINGS

FIG. 1 is a simplified high-level block diagram of the fast pattern matching system, in accordance with one embodiment of the present invention.

FIG. 2 shows various functional blocks of the compressed database pattern retriever shown in FIG. 1, in accordance with one embodiment of the present invention.

FIG. 3 shows various functional blocks of the compressed database pattern retriever, in accordance with another embodiment of the present invention.

FIG. 4 shows various functional blocks of the compressed database pattern retriever, in accordance with another embodiment of the present invention.

FIG. 5A shows various fields of a hash value as used by the compressed database pattern retriever of FIG. 4, in accordance with one embodiment of the present invention.

FIG. 5B shows various fields of each addressable entry stored in the first memory table as used by the compressed database pattern retriever of FIG. 4, in accordance with one embodiment of the present invention.

FIG. 5C shows various fields of each addressable entry in the second memory table as used by the compressed database pattern retriever of FIG. 4, in accordance with one embodiment of the present invention.

FIG. 5D shows various fields of each addressable entry in the second memory table as used by the compressed database pattern retriever of FIG. 4, in accordance with another embodiment of the present invention.

FIG. 6 shows a match validator 260 configured to perform memory bypassing, in accordance with one embodiment of the present invention.

FIG. 7 is a simplified high-level block diagram of a fast pattern matching system, in accordance with another embodiment of the present invention.

FIG. 8 is a flowchart of steps carried out to generate hash values, as known in the prior art.

FIG. 9 is a simplified block diagram of a hash value calculator, in accordance with one embodiment of the present invention.

FIG. 10 shows a multitude of M-bit hash values generated by padding associated input N-gram patterns.

### DETAILED DESCRIPTION OF THE INVENTION

In accordance with one embodiment of the present invention, incoming network traffic is compressed using a hash function and the compressed result is used by a space-and-time efficient retrieval method that compares it with entries in a multitude of databases that store compressed data. In accordance with another embodiment of the present invention, incoming network traffic is used for comparison in the databases without being compressed by the hash function. The present invention, accordingly, accelerates the performance of content security applications and networked devices such as gateway anti-virus and email filtering appliances.

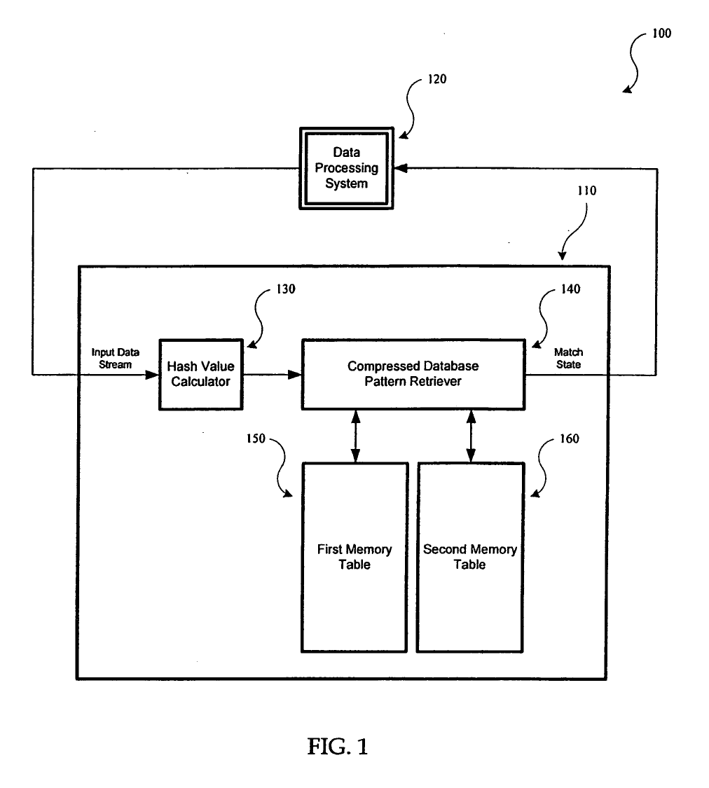

FIG. 1 is a simplified high-level diagram of a system 100 configured to match patterns at high speeds, in accordance with one embodiment of the present invention. System 100 is shown as including a pattern matching system 110 and a data processing system 120. In one embodiment, data processing system 120 is a network security system that implements one or more of anti-virus, anti-spam, intrusion detection algorithms and other network security applications. System 100 is configured so as to support large pattern databases. Pattern matching system 110 is shown as including a hash value calculator 130, a compressed database pattern retriever 140, and first and second memory tables 150, and 160. It is understood that memory tables 150 and 160 may be stored in one, two or more separate banks of physical memory.

Incoming data byte streams are received by the pattern matching system 110 hash value calculator 130. Hash value calculator 130 is configured to compute the hash value for a substring of length N bytes of the input data byte stream (alternatively referred to hereinbelow as data stream). Compressed database pattern retriever 140 compares the computed hash value to the patterns stored in first and second memory tables 150, and 160, as described further below. If the compare results in a match, a matched state is returned to the data processing system 120. A matched state holds information related to the memory location at which the match occurs as well as other information related to the matched pattern, such as the match location in the input data stream. In one embodiment, if the computed hash value is not matched to the compressed patterns stored in first and second memory tables 150, 160, a no-match state is returned to the data processing system 120. In another embodiment, if the computed hash value is not matched to the compressed patterns stored in first and second memory tables 150, 160, nothing is returned to the data processing system.

A matched state may correspond to multiple uncompressed patterns. If so, data processing system 120 disambiguates the match by identifying a final match from among the many candidate matches found. In such embodiments, data processing system 120 may be configured to maintain an internal database used to map the matched state to a multitude of original uncompressed patterns. These patterns are then compared by data processing system 120 to the pattern in the input data stream at the location specified by the matched state so as to identify the final match.

Since hash value calculator 130 maps many substrings of length N bytes of the input data stream into a fixed sized pattern search key, there may be instances where a matched state may not correspond to any uncompressed pattern. Data processing system 120 is further configured to disambiguate the matched state by verifying whether the detected matched state is a false positive. It is understood that although the data processing system 120 is operative to disambiguate and verify matched state, the present invention achieves a much faster matching than other known systems.

Compressed database pattern retriever 140 includes logic blocks configured to retrieve patterns from the memory tables that contain compressed databases. Such a format is non-ambiguous if overlapping patterns are not used, but becomes ambiguous when overlapping patterns are used. Such ambiguity of the patterns in the database is controlled via the compression algorithm used to generate the memory tables. Allowing ambiguous patterns increases the capacity of the database and also increases the amount of processing that data processing system 120 performs to resolve ambiguity in the patterns, as described above. The ambiguity just described does not relate to the collision of pattern search keys resulting from hashing operations. Instead, it applies only to the intentional overlapping of different pattern search keys in order to conserve memory.

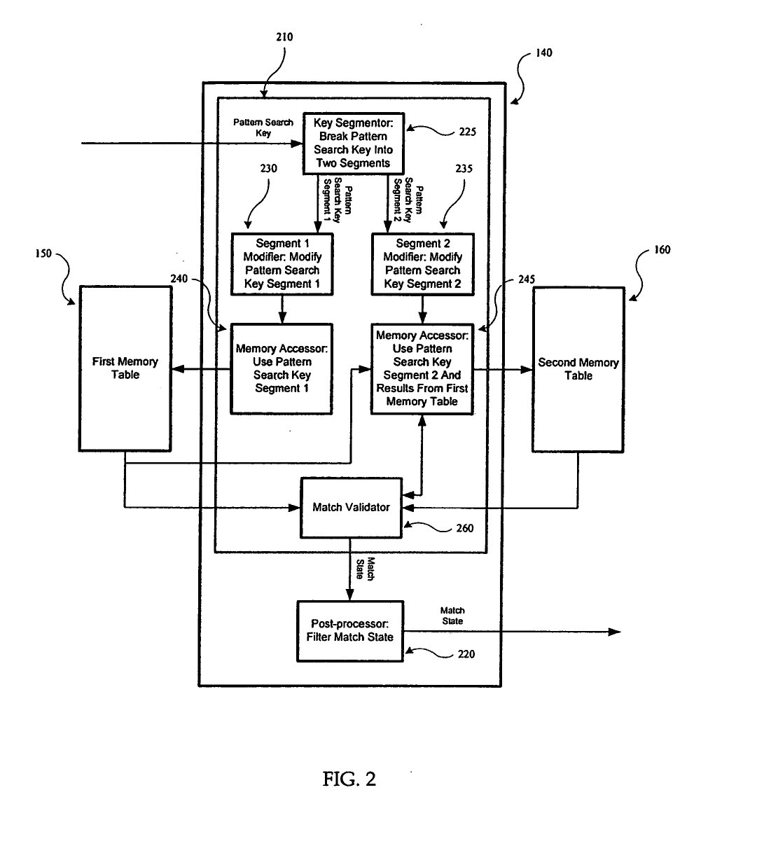

FIG. 2 is a block diagram of some of the components of database pattern retriever 140, in accordance with one embodiment of the present invention. Database pattern retriever 140 is shown as including a pattern search key segmentor 225, segment 1 modifier 230, segment 2 modifier 235, memory accessor 240, memory accessor 245, and match validator 260, collectively form memory lookup module 210, which is configured to perform the hash value pattern matching (hereinafter “hash value” is alternatively, and more generically, referred to as “pattern search key” because it is used as the query pattern in compressed memory lookups). Post-processor 220 is configured to perform post-processing on the matched state. Incoming fixed-length pattern search key supplied by hash value calculator 130 is divided into two segments, namely pattern search key segment 1 and pattern search key segment 2, by search key segmentor 225. In one embodiment, an input pattern search key of size 32-bits is divided into two equal-sized 16-bit segments. The first segment is supplied to segment 1 modifier 230, and the second segment is supplied to segment 2 modifier 235.

Pattern search key segment 1 is modified by segment 1 modifier and supplied to memory accessor 240. Pattern search key segment 2 may or may not be modified by segment 2 modifier and subsequently supplied to memory accessor 245. Such modifications include, for example, arithmetic operations, bitwise logical operations, masking and permuting the order of bits. Memory accessor 240 receives the modified segment 1 as an address to perform a read operation on first memory table 150. The data read by memory accessor 240 from first memory table 150 is combined with the output of segment 2 modifier 235 by memory accessor 245 to compute the address for the read-out operation in second memory table 160. In some embodiments, memory accessor 245 adds the data read from first memory table 150 to the output of segment 2 modifier 235 to compute the address for the read-out operation in second memory table 160. In yet other embodiments, memory accessor 245 adds an offset to the sum of the data read from first memory table 150 and the output of segment 2 modifier 235 to compute the address for the read-out operation in second memory table 160. Data read from first memory table 150 and second memory table 160 is supplied to match validator 260 which is configured to determine if the input pattern search key is a valid pattern.

In one embodiment, if the data read from the second memory table 160 includes the corresponding address of the first memory table 150 used to compute the address of the data read from the second memory table 160, match validator 260 generates a matched state signal. In such embodiments, if the data read from the second memory table 160 does not include the corresponding full or partial address of the first memory table 150 used to compute the address of the data read from the second memory table 160, match validator 260 generates a no-match signal. In another embodiment, if the data read from the second memory table 160 matches an identifier stored in the corresponding address of the first memory table 150 used to compute the address of the data read from the second memory table 160, match validator 260 generates a matched state signal. In such embodiments, if the data read from the second memory table 160 does not match the identifier stored in the corresponding address of the first memory table 150 used to compute the address of the data read from the second memory table 160, match validator 260 generates a no-match signal. Match validator 260 outputs a matched state that is used by a post processor 220 to identify the pattern that matched. In one embodiment, the post-processor 220 is used to block the first N-1 invalid results where the N-gram recursive hash is used, as described further below.

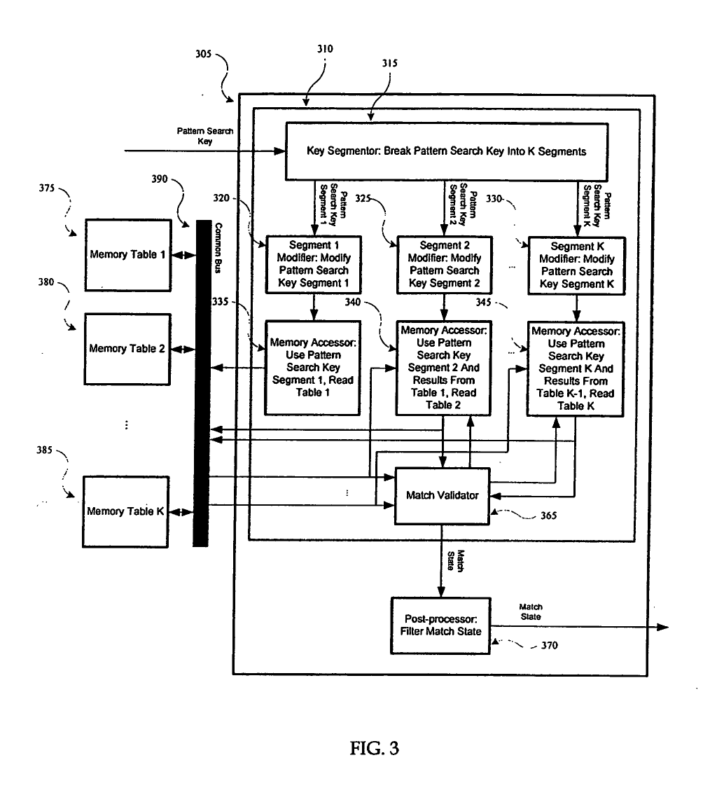

It is understood that other embodiments of the present invention may use more than two memory tables, that may or may not be stored in the same physical memory banks or device. FIG. 3 shows, in part, various block diagrams of a compressed database pattern retriever 305, in accordance with one embodiment of the present invention, adapted to use K memory tables. A common bus 390 is used for transferring data to/from the K memory tables. In some embodiments, multiple busses may be used to transferring data to/from the K memory tables.

Compressed database pattern retriever 305 may output a match state from the match validator module 365 prior to receiving the results from all of the K memory tables. In other words, match validator 365 may return a matched state after the i-th memory table has been read, where i is less than K and the first memory table is identified with i equal to zero. Such a situation may arise if match validator 365 receives sufficient information from reading the first i memory tables to enable match validator 365 to determine that the input pattern search key corresponds to a positive or negative match, thereby increasing the matching speed as less memory lookups are required. As such, compressed database pattern retriever 305 may bypass reading the remaining (K-(i+1)) memory tables and thus may begin to process the next pattern search key. Therefore, because pattern search keys are compared and matched state results are produced at a higher rate a pattern matching system, in accordance with the present invention, has an increased throughput.

In one embodiment, the pattern search keys passed to the compressed database pattern retriever, such as compressed database pattern retriever 140 and 305 of FIGS. 2 and 3, are generated by a hash value calculator, such as hash value calculator 130 of FIG. 1, configured to calculate a hash value from the input data stream. The hash values so calculated are used for hash value matching by comparing the hash value calculated at the current position in the input stream against a pre-loaded database of hash values stored in the memory tables. The pre-loaded database contains the hash values of training patterns. As is understood, the databases containing the hash values are generated from a collection of training patterns and loaded into the memory tables, such as memory table 150 and second memory table 160 of FIG. 1, prior to any matching operations. In another embodiment, a predetermined selection of bits is extracted from the input stream and is appended to the corresponding hash value, and the appended result is delivered to compressed database pattern retriever 140. This is achieved by combining parts of the original pattern with the calculated hash value, and using the combined result for looking up in the compressed database. Such an embodiment is advantageous if the statistics of the original patterns assist in the compressed database lookup step. For example, the original patterns may possess properties that can be utilized to increase pattern discrimination ability, thus allowing match validator 365 to make a match decision by reading from only a subset of memory tables. The result is an increase in speed of the overall matching process.

In one embodiment, the hash function used by hash value calculator 130 is implemented using recursive hash functions based on cyclic polynomials, see for example, “Recursive Hashing Functions for n-Grams”, Jonathan D. Cohen, ACM Transactions on Information Systems, Vol. 15, No. 3, July 1997, pp. 291-320, the content of which is incorporated herein by reference in its entirety. The recursive hash function operates on N-grams of textual words or binary data. An N-gram is a textual word or binary data with N symbols, where N is defined by the application. In general, hash functions, including those that are non-recursive, generate an M-bit hash value from an input N-gram. Typically a symbol is represented by an 8-bit byte, thus resulting in N bytes in an N-gram. The hash functions enable mapping an N-gram into bins represented by M bits such that the N-grams are uniformly distributed over the 2^{M} bins. An example of a typical value of N is 10, and M is 32.

Non-recursive hash functions re-calculate the complete hash function for every input N-gram, even if subsequent N-grams differ only in the first and last symbols. In contrast, the recursive variant can generate a hash value based on previously encountered symbols and the new input symbol. Therefore, computationally efficient recursive hash functions can be implemented in either software, hardware, or a combination of the two.

In one embodiment, the recursive hash function is based on cyclic polynomials. In another embodiment, the recursive hash function, may use self-annihilating algorithms and is also based on cyclic polynomials, but requires N and M to both be a power of two. In self-annihilating algorithms, the old symbol of an N-gram does not have to be explicitly removed. The following is an exemplary a recursive hash function based on cyclic polynomials, written in C++ and adapted for hardware implementation:

// Calculate hash values using “m_originalMem” as the input data stream, and
// “m_hashedValueMem” is the output data stream.
// Note that the first (m_nGramLength − 1) *m_numAddressBytes bytes are invalid
// at the output.
unsigned int CPRecursiveHash::CalcHash(unsigned int inputLen)
{

int i;
unsigned int k;
int hashIndex = −1;
unsigned int tempHashWord;
for ( i = 0; i < (int)inputLen; ++i )
{

// perform hashing
m_hashword = SlowBarrelShiftLeft(m_hashWord, m_delta);
m_hashWord \hat{ }= m_transformationT[m_originalMem[i]];
if ( i >= m_nGramLength )
{

m_hashWord \hat{ }= m_transformationTPrime[m_nGramBuffer[0]];

}
// update ngram fifo buffer
memmove((void *)&m_nGramBuffer[0], (void *)&m_nGramBuffer[1], m_nGramLength − 1);
m_nGramBuffer[m_nGramLength − 1] = m_originalMem[i];
// use the hash value (stored in m_hashWord), and/or send it to output
// note that this hash value can be used directly (or an offset added to it)
// to address a pattern memory,
// the code below is just an example of a possible use of the hash value
tempHashWord = m_hashWord;
for ( k = 0; k < m_numAddressBytes; ++k )
{

m_hashedValueMem(++hashIndex] = tempHashWord & 0xFF;
tempHashWord >>= 8;

}

}
return hashIndex + 1;

}
inline unsigned int CPRecursiveHash::SlowBarrelShiftLeft(unsigned int input,

unsigned int numToShift)

{

return (input << numToShift) | ((input >> (m_numWordBits − numToShift)));

}

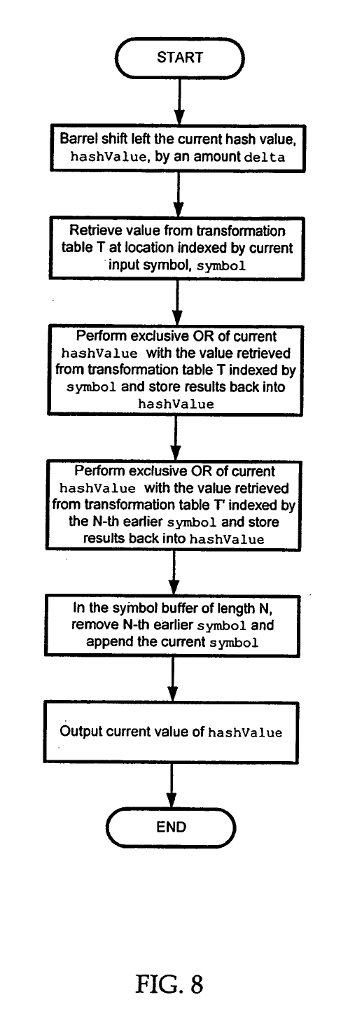

FIG. 8 is a flowchart of steps carried out to generate hash values corresponding to the above code. The algorithm requires the use of two look-up tables called transformation T and T′. In the example shown, each table has 256 entries with each entry corresponding to a symbol. The word size of each entry is set equal to or greater than the word size of the hash values. Therefore, the size of each entry must be at least as large as the desired number of hash value bits, shown as being equal to M. The sizes of these look-up tables are relatively small. Thus in a hardware implementation using Field Programmable Gate arrays (FPGA), the tables can be stored internally within the FPGA instead of requiring fast external memory.

The inverse transformation table T′ is derived from the transformation table T, so the values in the table T determines the actual hash function that maps input symbols to hash values. The transformation table T is used to contribute an input symbol to the overall hash value. Conversely, the inverse transformation table T′ is used to remove the contribution of input symbol to the hash value. When an input symbol is encountered in the input stream, a new hash value is calculated from the input symbol, the transformation table T and the current hash value. The contribution of this symbol to the hash value is removed N symbols later. This description assumes that an input data symbol corresponds to a single 8-bit input byte; therefore each table has 256 entries. However, the size of the input data symbol may be greater or less than a single 8-bit byte, so the sizes of the tables are correspondingly larger or smaller.

Referring to FIG. 1, the hash value generated by the hash value calculator 130 is used by the compressed database pattern retriever 140, as described above, to determine whether data at a corresponding address in the second memory table 160 relates to the hash value (i.e., the corresponding address of the entry in the first memory table 150) supplied by hash value calculator 130 used to determine the corresponding address in the second memory table 160. First and second memory tables store partial pattern search key values that are used to verify a positive match.

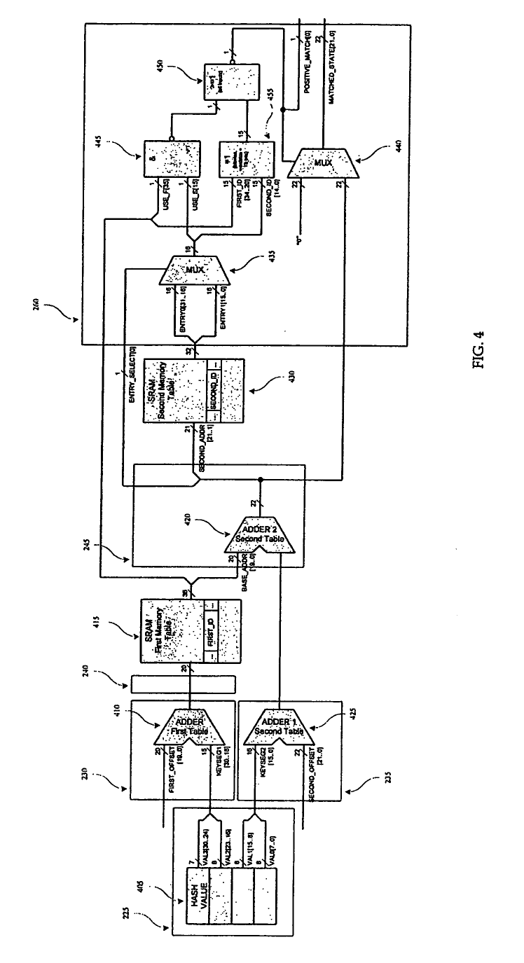

FIG. 4 shows one embodiment of the compressed database pattern retriever 140 in which segment 1 modifier 230 adds an offset value, FIRST_OFFSET, to the numerical value of the first pattern search key segment, KEYSEG1; adder 410 performs this addition. Similarly, segment 2 modifier 235 adds an offset value, SECOND_OFFSET, to the numerical value of the second pattern search key segment, KEYSEG2; adder 425 performs this addition. The memory accessor 240 for the first key segment shown in FIG. 4 performs an identity operation, that is, the input is passed to the output without modification. The memory accessor 245 for the second key segment shown in FIG. 4 adds the result from the first memory read operation to the result of the segment 2 modifier 235; adder 420 performs this addition. The values read from first memory table 415 and second memory table 430 are compared to determine if a valid match has occurred. This comparison can be performed using exemplary logic blocks 435, 440, 445, 450 and 455 which are collectively shown in FIG. 4 as forming match validator 260. In the embodiment shown in FIG. 4, a fixed-sized first memory table 415 is used with a variable-sized second memory table 430, where the size is determined by the compression algorithm and the training patterns used to generate the tables. In one embodiment, the size of each word in memory is 36 bits wide, and the number of first memory table 415 locations used is equal to 2¹⁵=32768 entries.

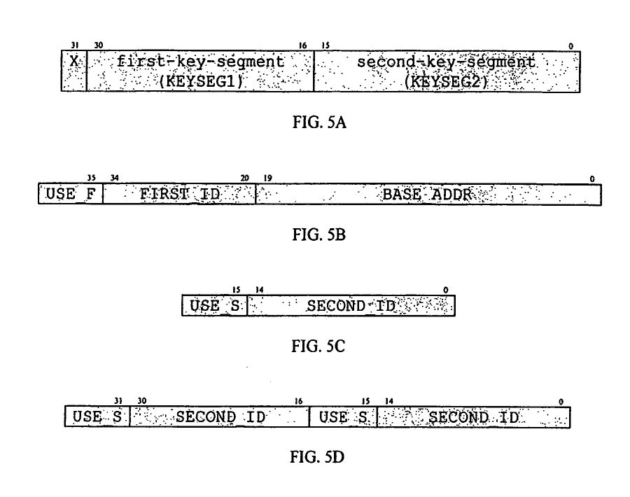

For illustration purposes, the exemplary embodiment shown in FIG. 4, uses a 32-bit hash value. Although a 32-bit hash value is generated, only 31 bits are assumed to be used by the key segmentor 225. These 31 bits are divided into two sub-keys. The first sub-key, shown in FIG. 5A as the first-key-segment and denoted as KEYSEG1 in FIG. 4, includes bits 30-16 of the hash value. The second sub-key, referred to in FIG. 5A as the second-key-segment and denoted as KEYSEG2 in FIG. 4 includes the least significant bits 15-0 of the hash value. The first-key-segment, KEYSEG1, is used as an address in the first memory table 415. The second-key-segment, KEYSEG2, is used as an offset to compute an address in the second memory table 430.

FIG. 5B shows various segments of each 36-bit entry in first memory table 415. Bit USE_F indicates whether the entry is valid. A bit USE_F of 0 indicates that the key being looked up does not exist in the database, thus obviating the need to access the second memory table 430. Bits 19-0 of an entry in the first memory table 415, denoted as BASE_ADDR, point to an address in the second memory table 430. Bits 34-20 of an entry in the first memory table 415 are denoted as FIRST_ID. In one embodiment, the value of FIRST_ID is set to be equal to KEYSEG1. Using a different value of FIRST_ID in first memory table 415 for a given KEYSEG1 parameter allows first-key-segments of the hash value to map to a different first-key-segment in the first memory table. This enables different hash values to logically, and not necessarily physically, to overlap each other in the first-key-segment in the second memory table 430. Logical overlapping may be required when memory has been exhausted and the addition of another hash value may result in at least one match with an existing entry. Overlapping patterns create ambiguous matches, but allows more patterns to be stored in the database. In an embodiment, an identifier for a pattern search key is derived from FIRST_ID and parts of BASE_ADDR. This identifier is then used in place of FIRST_ID in subsequent operations.

FIG. 5C shows various segments of each 16-bit entry in an exemplary second memory table 430 associated with this illustration. Each entry includes a use bit, denoted as USE_S, and a data field denoted as SECOND_ID for storing a first-key-segment. During the compression process, the SECOND_ID field of a second memory table 430 entry is set to the corresponding value of KEYSEG1 field that generated that entry's address. In this embodiment, the value of SECOND_ID field must match the value of FIRST_ID for a positive match to occur. Furthermore, it is understood that more entries may be stored into wider memories. For example, if 32 bit-wide memories are used for the second memory table 430, then two USE_S and two SECOND_ID values may be stored in each entry of the second memory table, as shown in FIG. 5D. In such a case, bits 31-16 may store the first sub-entry, collectively referred to as the first-sub-entry. Similarly, bits 15-0 may store the second sub-entry, collectively referred to as the second-sub-entry. The logical meaning of each sub-entry is identical. Using two sub-entries for each entry in second memory table 430 reduces the memory usage in the table by half. Using wider memories enables a plurality of sub-entries to be stored in each memory location.

In the embodiment shown in FIG. 4, the second memory table 430 is shown as being 32-bits wide. Each entry in memory table 430 includes two USE_S bits and two SECOND_ID bits. Bit 0, named ENTRY_SELECT of the address SECOND_ADDR supplied to second memory table 430 is used to select which USE_S bit and which SECOND_ID values to use in match validator 260. The SECOND_ID values for each entry in the second memory table 430 are denoted as ENTRY0 and ENTRY1. The signal ENTRY_SELECT is used to select between ENTRY0 and ENTRY1 by the multiplexer 435.

In the above exemplary embodiment, each hash value is shown as including 32 bits. Allocating one extra bit to each hash value doubles the amount of overall space addressable by the hash value, thus reducing the probability of unwanted collisions in the compressed memory tables. However, it also increases the number of bits required for the FIRST_ID and/or SECOND_ID fields as more hash value bits would require validation. The sizes of FIRST_ID and SECOND_ID are limited by the width of the memories. Therefore, using 32 bit hash values require an extra bit for the FIRST_ID field and this can be accomplished by a corresponding reduction in the number of bits used to represent BASE_ADDR in the second memory table, because the full width of the memories are already utilized. In one embodiment, the number of bits allocated to BASE_ADDR does not need to be reduced when the number of bits allocated to FIRST_ID is increased. This is achieved by having FIRST_ID and BASE_ADDR sharing one or more bits. However, there are some restrictions on the values of FIRST_ID and BASE_ADDR that can be used. These restrictions depend on which bits of FIRST_ID and BASE_ADDR are shared.

In the above example, BASE_ADDR is represented by 20 bits; thus permitting the use of an offset into the second memory table 430 that can address up to 2²⁰=1,048,576 different locations. A reduction in the space addressable by BASE_ADDR reduces the total amount of usable space in the second memory table 430, which increases the number undesirable of pattern search key collisions. It is understood that more or fewer hash value bits may be used in order to increase or reduce the number of unwanted pattern search key collisions, and the number of bits available to BASE_ADDR may decrease to the point where the actual number of unwanted pattern search key collisions may actually increase due to the reduction in the amount of addressable space in the second memory table 430.

Referring to FIG. 4, in one embodiment, after receiving a new hash value, the value of KEYSEG1 is added to a pre-determined and constant offset, FIRST_OFFSET, to compute an address for the first memory table 415. In the above example, KEYSEG1 includes 15 bits, thus requiring a first memory block that includes 2¹⁵=32,768 entries. The use of the offset, namely FIRST_OFFSET, parameter facilitates the use of multiple blocks of first-key-segments in the first memory table 415. This enables multiple independent pattern databases to be stored within the same memory tables and is achieved by using different FIRST_OFFSET values for different pattern databases. The values are chosen in a manner that allows the compressed pattern databases to remain independent of each other.

The base address, BASE_ADDR, retrieved from the first memory table 415 at the location defined by the parameters KEYSEG1 and FIRST_OFFSET, is subsequently added to a second constant and pre-determined offset value, denoted as SECOND_OFFSET, and further added to parameter value KEYSEG2 to determine an address in the second memory table 430. The offset, SECOND_OFFSET, facilitates the use of multiple second-key-segment blocks that correspond to different hash functions. Therefore, multiple and independent pattern databases can be stored in the same memory tables by using appropriate values for SECOND_OFFSET.

Since in the above exemplary embodiment, the second memory table 430 is a 32-bit memory, the least significant bit of the computed address for the second memory table 430 is extracted and used to select one of the inputs of the multiplexer 435. The upper 21 bits are used as the actual address for the second memory table 430. This allows two SECOND_ID parameters to be stored for every 32-bit entry in second memory table 430. The least significant bit of the second memory table address is used to select the specific SECOND_ID. In FIG. 5D, the use bits corresponding to the first and second SECOND_ID parameters are denoted as USE_S.

In order for a positive match to occur the use-bits, USE_F and USE_S, have to be set. During the pattern compression process, a use bit is set if the entry stores a corresponding training pattern, otherwise it is cleared. The use bits are set or cleared when the training patterns are compiled, compressed and loaded into the tables. Therefore, a cleared use bit indicates a no-match condition. In some embodiments, if the use-bit in the first memory table is cleared then the lookup of the second memory table 430 may be bypassed so that the next processing cycle can be allocated to the lookup of the first memory table 415 instead of the second memory table 430, therefore, the next match cycle begins in the first memory table 415 and the second memory table 430 is not accessed. In such situations, the match validator 260 has the ability to send a signal back to memory accessors down the chain of memory accessors that further reads are not required. Consequently, the overall system operates faster because extra memory lookups are not required.

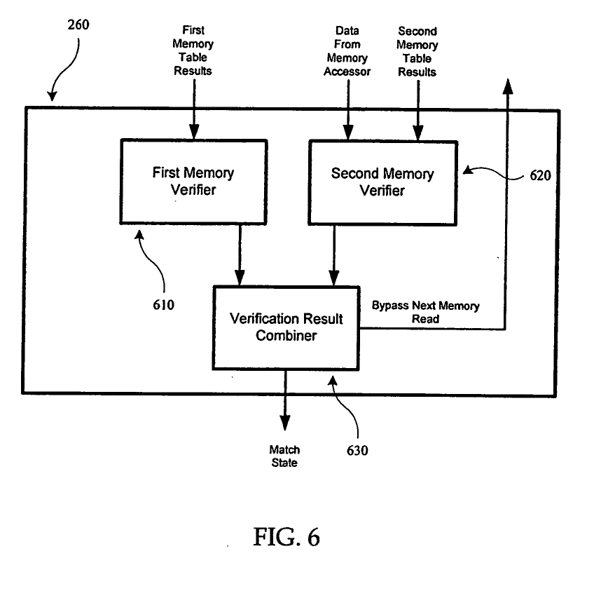

FIG. 6 illustrates one embodiment of a match validator 260 that implements memory bypassing in the context of two memory tables. Results from reading the two memory tables are verified independently by first memory verifier 610 and second memory verifier 620. The verification result combiner 630 is configured to examine the result from the first memory verifier 610, and if a positive match occurs, signal Bypass_Next_Memory_Read signal is generated causing the memory accessor not to proceed with the next read cycle. Furthermore, for a positive match to occur, FIRST_ID must be equal to SECOND_ID, and this comparison for equality can be done using an XOR 455 operation performed bitwise on the two 15 bit words. The results of all these comparisons are combined using a NOR 450 operation to derive a single positive/negative match output signal that selects an output multiplexer 440. Multiplexer 440 output zeros if that match signal is low, otherwise the address of the positively matched second memory table 430 entry is passed to the output. That positive/negative match signal is also made available at the output as a separate line.

In practice, it is desirable to have M as large as possible so that an input N-gram is mapped to a large universe of hash values with minimal overlapping between different input N-grams. Using a large value of M means that one cannot directly use the hash values to address a physical memory, because the number of required memory addresses will be too large. For example, using a value of 31 for M implies that a physical memory size of 2³¹=2,147,483,648 entries is required in order for the hash values to directly address this memory space. However, the total number of unique N-grams that need to be represented is usually very much less than 2³¹. In other words, the universe of all possible hash values is usually sparsely populated by the database of patterns that hash into it. The present invention takes advantage of this property to reduce the space required to store the hash values of a corresponding pattern database to one that is of the order of the number of unique N-grams.

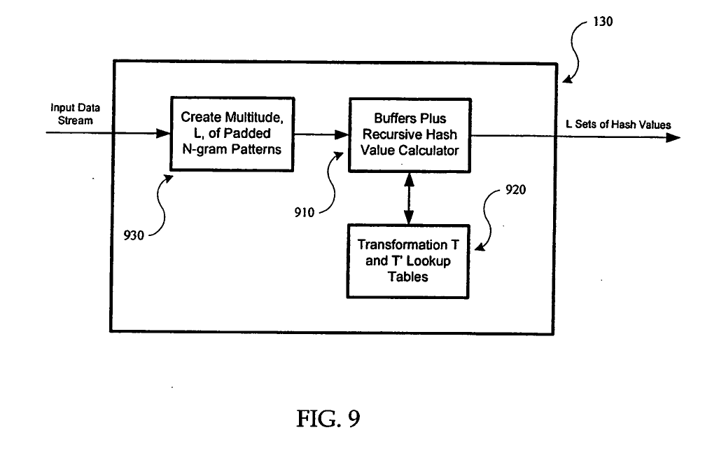

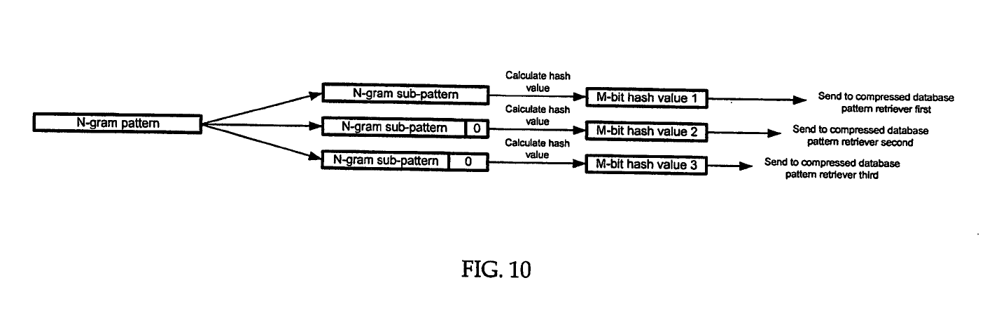

In the embodiments described above, the training patterns with length less than N are not stored in the compressed memory format. In FIGS. 9 and 10, training patterns with length less than N are used. Here, training patterns with length less than N are padded with zero bit values to derive padded patterns of length N, which are then stored in the said compressed memory tables. In order to match input data byte streams against all patterns stored in the compressed memory tables, including those training patterns that have been padded to length N, the N-grams extracted from the input data byte stream is truncated and padded (see FIG. 10). FIG. 9 shows, in part, some of the blocks disposed in hash value calculator 130 configured to use recursive hash functions, as known by those skilled in the art. Block 930 is configured to receive the input data stream and generate L padded N-gram patterns, where L is an integer greater than or equal to 1. The value of L is determined by the number of different length training patterns that have lengths less than or equal to N. Block 910 is configured to buffer each of the padded N-gram patterns and to supply a corresponding M-bit hash value one at a time. Each of transformation tables (T, T′) 920, includes 256 entries, and the word size of each entry is set to be equal to or greater than the size of the hash values.

Hash value calculator 910 generates the M-bit hash value, which is then used by the memory lookup module 210 to retrieve the corresponding entry in the compressed first and second memory tables 150, and 160. If a matching entry is detected in the memory tables, memory lookup module 210 outputs a valid matched state, where state is the address of the second memory table corresponding to the matched hash value. Due to the nature of the recursive hash function, match results corresponding to the first (N-1) symbols are invalid, which are discarded by the post-processor 220.

FIG. 10 shows how the multitude of M-bit hash values are generated from padding the input N-gram pattern. As shown in FIG. 10, the input N-gram pattern is repeatedly truncated and appended with zeros to create new padded N-gram patterns for hashing.

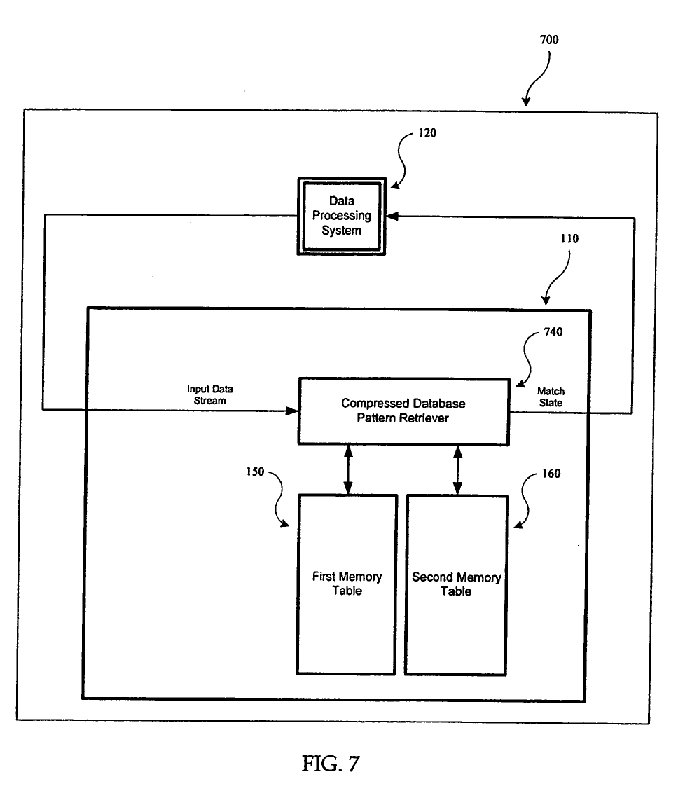

FIG. 7 is a simplified high-level diagram of some of the blocks disposed in the fast pattern matching system, in accordance with another embodiment 700 of the present invention. This embodiment does not include a hash value calculator. In the embodiment 700, input data stream is directly supplied to compressed database pattern retriever 740. The operations of the compressed database pattern retriever 740, and also that of the compression algorithm used to compress the data stored in the memory tables is independent of hash value calculation. In the embodiment 700, the compressed database pattern retriever 740 extracts constant length patterns from the input data stream (i.e., stream of patterns) for processing. In one embodiment, this constant length is 32 bits long. This embodiment is similar to passing an N-gram length value to the compressed database pattern retriever where N has been set to 32 bits. If a database is trained with patterns that are of variable length, then various methods may be used to force the data extracted from the input data stream to have constant length. For example, the database may contain patterns that have lengths ranging from 16 bits to 180 bits long, and the length expected by compressed database pattern retriever 740 may be 32 bits long. Then, in one embodiment, patterns that are less than 32 bits in length may be padded with zero-value bits to force them to have a constant length of 32 bits. Patterns that are more than 32 bits in length can be truncated to 32 bits. Similarly, when hash value calculators are used, shorter length patterns may be padded and then mapped using a hash function to obtain a value that is shorter in length, which is then compressed and stored using one of the disclosed methods.

In one embodiment, the above invention may be used together with a finite state machine that also performs pattern matching. Instead of padding patterns with length less than N as described above and illustrated by FIG. 9 and FIG. 10, a finite state machine (FSM), or some other appropriate pattern matching engine (PME), may be used to perform matching on shorter length patterns. The FSM or PME does not replace any of the functional blocks of the embodiments disclosed herein, and instead, performs parallel input data pattern matching against training patterns that have length less than N. In such embodiments, the FSM or PME pattern matcher stores training patterns whose lengths are less than N bytes, thereby enabling the embodiments described above to handle training patterns whose lengths are equal to or greater than L. Embodiments that include an FSM or PME, in addition to the other blocks described above, also obviate the need to truncate and pad the input data byte stream, so the value of L in FIG. 9 can be set to one. By combining the current invention with an FSM or PME, a complete pattern matcher is obtained that can operate with training patterns of any length. It is understood that any other appropriate pattern matching engine not based on a finite state machine may also be used to achieve the same results. As known to those trained in the art, a finite state machine can be implemented using systems and methods such as those disclosed in U.S. patent application No. US 2005/0035784 and U.S. patent application No. US 2005/0028114.

One or more of the memory accessor modules 240,245, 335,340, 345 can implement the identity operation. That is, they do not perform any memory lookups or functions other than passing the input to the output without modification. The input to the memory accessor modules are modified key segments. So, in this embodiment, the values of modified key segments transmitted to memory accessor modules implementing the identity operation are passed directly to the match validator 365. In such embodiments, match validator 365 contains decision logics that are functions of only the modified key segments and there are no dependencies on memory table values.

Although the foregoing invention has been described in some detail for purposes of clarity and understanding, those skilled in the art will appreciate that various adaptations and modifications of the just-described preferred embodiments can be configured without departing from the scope and spirit of the invention. For example, other pattern matching technologies may be used, or different network topologies may be present. Moreover, the described data flow of this invention may be implemented within separate network systems, or in a single network system, and running either as separate applications or as a single application. Therefore, the described embodiments should not be limited to the details given herein, but should be defined by the following claims and their full scope of equivalents.

What is claimed is:

1. A system for matching patterns comprising:
first and second memory tables each configured to store entries in a compressed format, the entries corresponding to training patterns;
a database pattern retriever configured to receive a multitude of bits defining a data pattern and representative of an incoming data stream, said database pattern retriever configured to retrieve an entry from the first memory table at a first address defined by the multitude of bits; said database pattern retriever further configured to read an entry from the second table at a second address defined by the entry read from the first memory table; said database pattern retriever further configured to generate a matched state if the entry read from the second memory table includes an identifier derived from the data pattern and entry in the first memory table.

2. The system of claim 1 wherein said database pattern retriever further comprises:
first segment modifier configured to receive a first portion of the data pattern and supply a first group of bits;
a first memory accessor configured to read the entry from the first memory table at the first address defined by the first group of bits;
a second segment modifier configured to receive a second portion of the data pattern and supply a second group of bits; and
a second memory accessor configured to read the entry from the second memory table at the second address defined by the second group of bits and the entry read from the first memory table.

3. The system of claim 2 wherein said second group of bits is the same as the second portion of data.

4. The system of claim 2 wherein said database pattern retriever further comprises:
a match validator configured to receive the first entry read from the first memory table and the second entry read from the second memory table, the match validator further configured to generate a matched state if the entry read from the second memory table includes a pattern matching the pattern of the first group of bits.

5. The system of claim 4 further comprising:
a processing unit configured to receive the matched state generated by the match validator and to identify the matched pattern.

6. The system of claim 1 wherein said multitude of bits represents a hash value.

7. The system of claim 6 further comprising:
a hash value calculator configured to generate the hash value from the incoming data stream.

8. The system of claim 7 wherein said database pattern retriever further comprises:
a post-processor configured to filter out invalid matches caused by the hash value calculator.

9. The system of claim 4 wherein each entry in the first memory table includes at least one use bit field and at least one key-segment field.

10. The system of claim 9 wherein each entry in the second memory table includes at least one use bit field and at least one key-segment field.

11. The system of claim 7 wherein the hash value calculator maps an input N-gram string to a hash value.

12. The system of claim 11 wherein the hash value calculator is configured to use a recursive hash function to generate a hash value associated with an input N-gram string.

13. The system of claim 7 wherein the hash value calculator is configured to supply fixed-length pattern search keys from incoming variable length data patterns.

14. The system of claim 1 wherein the address for the first memory table is further defined by a first offset.

15. The system of claim 1 wherein the address for the second memory table is further defined by a second offset.

16. The system of claim 1 wherein said database pattern retriever is further configured to receive the data pattern one symbol at a time.

17. The system of claim 1 wherein said database pattern retriever is further configured to receive the data pattern multiple symbols at a time.

18. A system for matching patterns comprising:
a key segmentor configured to receive and divide a pattern search key associated with incoming data stream into K segments;
K segment modifiers each configured to receive a different one of the K segments;
K memory accessors each associated with a different one of the K segment modifiers and configured to receive an output segment supplied by its associated segment modifier;
K memory tables each configured to store compressed entries and each associated with a different one of the K memory accessors; wherein each of the K memory tables is configured to supply data at an address defined by an associated segment modifier; wherein said K memory tables are further configured to be accessed in sequence;
a match validator coupled to each of a subset of the K memory accessors and configured to receive data from the K memory tables, said match validator further configured to detect a matched state if a data read from a first one of the memory tables includes in-part or in entirety the address of any of the memory tables accessed prior to accessing the first one of the memory tables.

19. The system of claim 18 wherein the output of at least one of the K segment modifiers is the same as the segment received by that segment modifier.

20. The system of claim 19 further comprising:
a hash value calculator configured to generate the pattern search key from the incoming data stream.

21. The system of claim 20 wherein said match validator is further configured to determine whether a matched state has occurred after reading from one or more of the K memory tables.

22. A method for matching patterns comprising:
storing compressed entries in each of first and second memory tables;
receiving a multitude of bits defining a data pattern and representative of an incoming data stream;
retrieving an entry from the first memory table at a first address defined by the multitude of bits;
retrieving an entry from the second table at a second address defined by the entry read from the first memory table; and
generating a matched state if the entry read from the second memory table includes the data pattern.

23. The method of claim 22 further comprising:
modifying a first portion of the data pattern to supply a first group of bits;
retrieving the entry from the first memory table at the first address defined by the first group of bits;
modifying a second portion of the data pattern to supply a second group of bits; and
retrieving the entry from the second memory table at the second address defined by the second group of bits.

24. The method of claim 23 wherein said second group of bits is the same as the second portion of data.

25. The method of claim 24 further comprising:
identifying the matched pattern.

26. The method of claim 25 wherein said multitude of bits represents a hash value.

27. The method of claim 26 further comprising:
filtering out invalid matches caused by the hash values.

28. The method of claim 27 wherein each entry in the first memory table includes at least one use bit field and at least one key-segment field.

29. The method of claim 28 wherein each entry in the second memory table includes at least one use bit field and at least one key-segment field.

30. The method of claim 29 further comprising:
mapping an input N-gram strings to the hash value.

31. The method of claim 30 further comprising:
using a recursive hash function to generate the hash value associated with the input N-gram string.

32. The method of claim 31 further comprising:
supplying fixed-length pattern search keys from incoming variable length data streams.

33. The method of claim 22 wherein the address for the first memory table is further defined by a first offset.

34. The method of claim 22 wherein the address for second first memory table is further defined by a second offset.

35. The method of claim 34 further comprising:
receiving the data pattern one symbol at a time.

36. The method of claim 34 further comprising:
receiving the data pattern multiple symbols at a time.

37. A method of matching patterns and comprising:
dividing a pattern of bits associated with incoming data stream into K segments;
storing compressed data in each of K memory tables, wherein each of the K segments is associated with an address for a different one of the K memory tables, and wherein the memory tables are adapted to be read sequentially; and
detecting a matched state if a data read from a first one of the K memory tables includes in-part or in entirety the address of any of the memory tables accessed prior to the first one of the memory tables.

38. The method of claim 37 wherein each of a subset of the K segments is a modified segment representative of the incoming data stream.

39. The method of claim 38 wherein the pattern of bits include bash values generated from the incoming data stream.

40. The method of claim 39 further comprising:
detecting whether a matched state has occurred after reading one or more of the K memory tables.

41. A method for matching patterns comprising:
storing compressed entries in each of first and second memory tables;
receiving a plurality of bits defining a data pattern and representative of an incoming data stream;
retrieving a first portion of a first entry from the first memory table at a first address defined by the plurality of bits;
retrieving a first portion of a first entry from the second table at a second address defined by the entry read from the first memory table; and
generating a matched state if a second portion of the first entry in the first memory table matches the second portion of the first entry in the second memory table.

42. A system for matching patterns comprising:
first and second memory tables each configured to store entries in a compressed format, the entries corresponding to training patterns;
a database pattern retriever configured to receive a plurality of bits defining a data pattern and representative of an incoming data stream, said database pattern retriever configured to retrieve a first portion of a first entry from the first memory table at a first address defined by the plurality of bits; said database pattern retriever further configured to retrieve an entry from the second memory table at a second address defined by the first portion of the first entry read from the first memory table; said database pattern retriever further configured to generate a matched state if the second portion of the first entry retrieved from the first memory table matches the second portion of the second entry retrieved read from the second memory table.
